(19) United States
(12) Patent Application Publication
(10) Pub. No.: US 2009/0004816 A1
(43) Pub. Date: Jan. 1, 2009

(54) METHOD OF FORMING ISOLATION LAYER OF SEMICONDUCTOR DEVICE

(75) Inventors: An Bae Lee, Seoul (KR); Yong Seok Eun, Gyeonggi-do (KR); Su Ho Kim, Gyeonggi-do (KR); Hye Jin Seo, Gyeonggi-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyeonggi-do (KR)

(21) Appl. No.: 11/949,960

(22) Filed: Dec. 4, 2007

(30) Foreign Application Priority Data
Jun. 28, 2007 (KR) 10-2007-0064753

(51) Int. Cl. H01L 21/762

(52) U.S. Cl. 438/425; 257/E21.546

(57) ABSTRACT

A method of forming an isolation layer in a semiconductor device using rapid vapor deposition to fill in a trench of the semiconductor device comprises forming a hydrophilic layer on the trench and forming a hydrophobic layer on a region other than the trench, and selectively forming a buried insulating layer in the trench using a catalytic reaction of the hydrophilic layer.

### CROSS-REFERENCE TO RELATED APPLICATION

The priority of Korean patent application number 10-2007-0064753, filed on Jun. 28, 2007, the disclosure of which is incorporated by reference in its entirety, is claimed.

### BACKGROUND OF THE INVENTION

The invention relates to a semiconductor device and, more particularly, to a method of forming an isolation layer, which is capable of selectively and uniformly being formed in a semiconductor device using a rapid vapor deposition process.

As semiconductor devices have become more highly integrated with a narrower width, Shallow Trench Isolation (STI) processes have become more important. The STI process for manufacturing the isolation layer includes the processes of forming a trench of a predetermined depth using an exposure technology and an etch process, filling in the trench with an insulating layer, and planarizing the insulating layer.

Meanwhile, high density plasma (HDP) processes are used to fill in the trench. However, the HDP process can adversely affect device quality due to damage to a silicon layer of a semiconductor substrate. Also, micro voids can be formed at a device separation region during the trench filling process using an HDP process. Thus, a conductive material may penetrate into a micro void and result in failure of the device in a subsequent process because of a short-circuit. In order to overcome this problem, a gap filling method, which fills in a portion of the trench with a fluent insulating layer and the remaining portion of the trench with an HDP oxide layer, is applied.

However, if the trench is filled through a two-step gap-filling method, the process is complicated and may result in a defect during the process of the deposition and thermal treatment of the fluent insulating layer which fills in the trench.

### SUMMARY OF THE INVENTION

Embodiments of the invention are directed to providing a method of forming an isolation layer, which is capable of selectively and uniformly being formed, in a semiconductor device using a rapid vapor deposition.

In one embodiment, a method of forming an isolation layer in a semiconductor device using a rapid vapor deposition comprises forming a trench on a semiconductor substrate, forming a hydrophobic layer on the semiconductor substrate including the trench, forming a hydrophilic layer on the hydrophobic layer only in the trench, and forming a buried insulating layer which fills in the trench by using a catalytic reaction of the hydrophilic layer. The hydrophilic layer preferably comprises an oxide layer, and the hydrophobic layer preferably comprises a polysilicon layer. The buried insulating layer is preferably formed by forming a catalytic alumina (Al₂O₃) layer on the hydrophilic layer by reacting gaseous tri-methyl aluminum (TMAl) with the hydrophilic layer, and forming an insulating layer which fills in the trench by growing the alumina layer by reacting the alumina layer with tris-(tert-alkoxy)-silanol supplied to the alumina layer. The alumina layer and the buried insulating layer are preferably formed by a rapid vapor deposition process at a pressure in the range of 1 Torr to 20 Torr and at a temperature in the range of 150° C. to 300° C.

In another embodiment, a method of forming an isolation layer in a semiconductor device using a rapid vapor deposition process comprises forming a trench in an isolation region of a semiconductor substrate having an active region and the isolation region, forming a hydrophobic layer on the semiconductor substrate including the trench and the active and isolation regions, forming an oxide layer on the hydrophobic layer overlying the trench and the isolation region by oxidizing a portion of the hydrophobic layer, etching the oxide layer formed over the active region to expose the hydrophobic layer in the active region, whereby the oxide layer remains in the isolation region, and forming a buried insulating layer over the oxide layer and filling in the trench in the isolation region but not the exposed hydrophobic layer. The hydrophobic layer preferably comprises a polysilicon layer. The hydrophobic layer is preferably formed by a low pressure chemical vapor deposition (LPCVD) process at a temperature in the range of 500° C. to 530° C. The oxide layer is preferably formed by an etch-back process, and the oxide layer is preferably formed by an anisotropic etching process. The buried insulating layer is preferably formed by forming an alumina (Al₂O₃) layer on the oxide layer by supplying gaseous tri-methyl aluminum (TMAl) to the oxide layer for reaction with the oxide layer, and forming an insulating layer which fills in the trench by growing the alumina layer by reaction of the alumina layer with tris-(tert-alkoxy)-silanol supplied to the alumina layer. The alumina layer and the buried insulating layer are preferably formed by a rapid vapor deposition process at a vapor pressure in the range of 1 Torr to 20 Torr and at a temperature in the range of 150° C. to 300° C.

### BRIEF DESCRIPTION OF THE DRAWINGS

FIGS. 1 to 8 are cross-sectional views illustrating a method of forming an isolation layer of a semiconductor device using a rapid vapor deposition method according to one embodiment of the invention.

FIG. 9 is an SEM photograph of a vapor deposited isolation layer according to one embodiment of the invention.

### DESCRIPTION OF SPECIFIC EMBODIMENTS

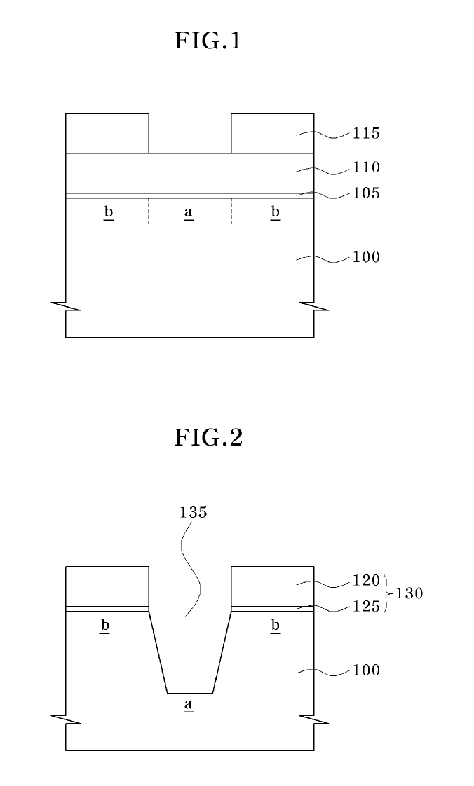

FIGS. 1 to 8 are cross-sectional views illustrating a method of forming an isolation layer of a semiconductor device using a rapid vapor deposition method.

Referring to FIG. 1, a pad oxide layer 105 and a pad nitride layer 110 are deposited on a semiconductor substrate 100. Here, the pad oxide layer 105 relaxes stress of the semiconductor substrate 100 caused by a tensile stress of the pad nitride layer 110. Next, the pad nitride layer 110 is coated with a photoresist layer and is patterned using photoresist patterns 115 so that a portion of the surface of the pad nitride layer 110 is exposed. Here, a region ‘a’, the exposed region of the pad nitride layer 110, is defined as a device separation region to be formed later and a region ‘b’, the blocked regions by the photoresist patterns 115, is defined as active regions.

Referring to FIG. 2, pad nitride patterns 120 are formed by etching the pad nitride layer 110 using the photoresist patterns 115 as an etching mask. Then, the photoresist layer pattern 115 is removed and patterned pad oxide layers 125, which expose the device separation region ‘a’ on a surface of the semiconductor substrate 100, are formed by etching the pad oxide layer 105 using the pad nitride patterns 120 as an etching mask. Then, hard mask layer patterns 130 including the patterned pad nitride layers 120 and the patterned pad oxide layers 125 are formed. A trench 135 having a predetermined depth is formed in the semiconductor substrate 100 using the hard mask layer patterns 130 as an etching mask.

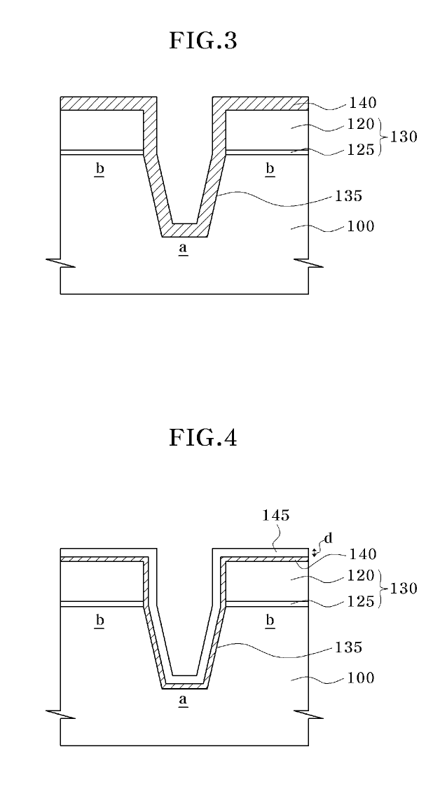

Referring to FIG. 3, a hydrophobic layer 140 is deposited on the resulting structure. Such a hydrophobic layer 140 secures a growth selectivity on the surface of the trench 135 in the following gap-filling process to fill in the trench 135. The hydrophobic layer 140 is illustratively and preferably formed of a polysilicon layer by a low pressure chemical vapor deposition (LPCVD) method. Specifically, in the illustrated embodiment, the semiconductor substrate 100 is loaded into a chemical vapor deposition (CVD) apparatus. Then, a source for vapor deposition material is supplied to the CVD apparatus. The vapor deposition source illustratively includes silane (SiH₄) and nitrous oxide (N₂O) gases. Next, when the vapor deposition source material (silane) is supplied to the low pressure CVD equipment at a temperature of approximately 500° C. to 539° C., the hydrophobic layer 140 is formed on the exposed surface of the trench 135 of the semiconductor substrate 100 and the hard mask layer patterns 130. As illustrated, the hydrophobic layer 140 can be transformed to an oxide layer in a subsequent oxidation process.

Referring to FIG. 4, a layer having a thickness of ‘d’ from the surface of the hydrophobic layer 140 is transformed to an oxide layer 145 through an oxidation process. Such an oxidation process is illustratively a dry oxidation process. In the dry oxidation process, oxygen (O₂) gas is supplied to form the oxide layer 145 having a thickness of ‘d’ from the surface of the hydrophobic layer 140. The oxide layer 145 is illustratively hydrophilic. According to such a dry oxidation process, a double layer of the hydrophobic layer 140 and the oxide layer 145, which is hydrophilic, is formed on the trench 135.

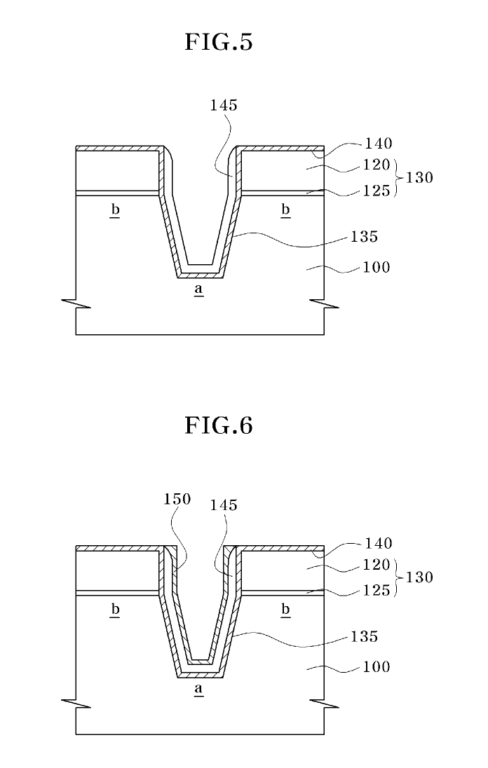

Referring to FIG. 5, a portion of the surface of the hydrophobic layer 140 is exposed by etching the oxide layer 145 which is formed on the hard mask layer pattern 130. Here, the active region ‘b’ is positioned under the exposed hydrophobic layer 140. The hydrophobic layer 140 is preferably etched using an etch-back process. At this time, an anisotropic etching process to etch the oxide layer 145 in a vertical direction is preferable so that the oxide layer 145 remains on the sidewalls of the trench 135. According to this etching process, the oxide layer 145 is exposed on the sidewalls of the trench 135 which is the trench region ‘a’, and only the hydrophobic layer 140 is exposed on the hard mask pattern 130 which defines the active region ‘b’.

Referring to FIG. 6, an alumina (Al₂O₃) monolayer 150 is formed on the oxide layer 145 of the trench 135 as a catalytic monolayer.

Specifically, gas phase tri-methyl aluminum (TMAl), as a precursor, is supplied on the oxide layer 145 to be formed as an insulating layer to fill in the trench 135. Then, the oxide layer 145 and the TMAl react with each other to form the catalytic monolayer 150. Then, the oxide layer 145 surface is covered with the catalytic monolayer 150 which comprises alumina (Al₂O₃). The catalytic monolayer 150 is preferably formed using a rapid vapor deposition (RVD) process. The RVD process is preferably performed at a temperature in the range of approximately 150° C. to 300° C. and at a pressure in the range of approximately 1 Torr to 20 Torr. At this time, the catalytic monolayer 150 is not formed on the hydrophobic layer 140 which is positioned on the active region ‘b’, but only formed on the oxide layer 145.

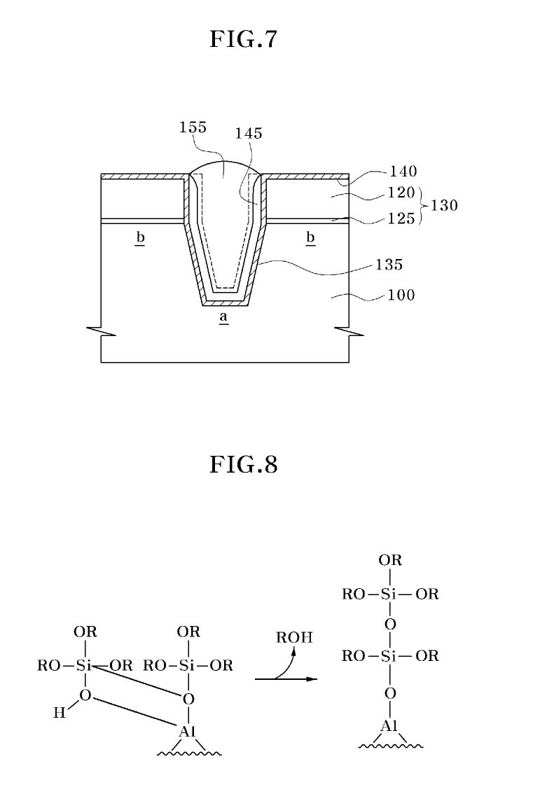

Referring to FIG. 7, a buried insulating layer 155, which fully fills in the trench 135, is formed by growing the catalytic monolayer 150 as a seed layer.

Illustratively, gaseous tris-(tert-alkoxy)-silanol is supplied to the oxide layer 145, which is covered with the catalytic layer 150. The tris-(tert-alkoxy)-silanol reacts at the catalytic layer 150 which covers the oxide layer 145, and the aluminum in the catalytic monolayer 150 is combined with the oxygen in the tris-(tert-alkoxy)-silanol. Here, tris-(tert-alkoxy)-silanol preferably comprises tris-(tert-pentoxy)-silanol.

At this time, as shown in FIG. 8, although one molecule of the tris-(tert-alkoxy)-silanol has already reacted at the catalytic layer 150, a plurality of tris-(tert-alkoxy)-silanol molecules can additionally react at the catalytic monolayer 150 covering the oxide layer 145 because other tris-(tert-alkoxy)-silanol molecules diffuse into the catalytic layer 150 and then additionally react to between the catalytic layer 150 covering the oxide layer 145 and the oxygen atoms which have been combined with the catalytic layer 150.

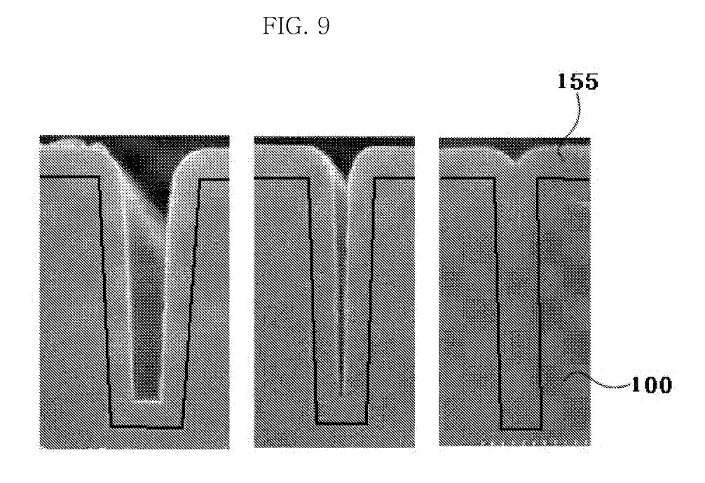

As a result, a siloxane macromolecule is formed in the catalytic monolayer 150 which covers the oxide layer 145 and the siloxane macromolecules react with each other to form a bridged bond. By this bridged bond, the silicon-oxygen bond in the catalytic monolayer 150 which covers the oxide layer 145 becomes to have a self-controlled, uniform characteristic throughout all regions as shown in FIG. 9. After repeating the process described above, the buried insulating layer 155 of a desired thickness can be uniformly grown. Based on the formation of the buried insulating layer 155 using the RVD process to which such an above-mentioned reaction is applied, a plurality of the molecule layers can be grown in each cycle of the catalytic reaction of the aluminum included in the catalytic layer 150. For example, a fast growth rate of 50 Å/cycle to 150 Å/cycle and excellent step coverage can be obtained.

Meanwhile, the trench 135 is fully filled with the buried insulating layer 155 which is formed through the RVD process by sufficiently increasing the reaction time required for the reaction at the oxide layer 145. Also, deposition on the hydrophobic layer 140 can be controlled by adjusting a purge time of the tris-(tert-alkoxy)-silanol. Accordingly, the trench 135 may be uniformly filled with the buried insulating layer 155. Also, the RVD process according to one embodiment of the invention is performed with the same uniformity as an atomic layer depostion (ALD) process and can obtain a fast growth rate per cycle from a surface polymerization, as compared with a conventional atomic layer deposition process having a slow film growth rate. Moreover, the problem of micro void formation caused by a plasma damage or a short-circuit in the gap filling in the HDP method can be prevented.

While the invention has been described with respect to the particular embodiments, various changes and modifications may be made without departing from the spirit and scope of the invention as defined in the following claims.

What is claimed is:

1. A method of forming an isolation layer in a semiconductor device using rapid vapor deposition, the method comprising:
forming a trench on a semiconductor substrate;
forming a hydrophobic layer on the semiconductor substrate including the trench;
forming a hydrophilic layer on the hydrophobic layer only in the trench; and
forming a buried insulating layer which fills in the trench by catalytically reacting the hydrophilic layer.

2. The method of claim 1, wherein the hydrophilic layer comprises an oxide layer.

3. The method of claim 1, wherein the hydrophobic layer comprises a polysilicon layer.

4. The method of claim 1, wherein the buried insulating layer is formed by:
forming a catalytic alumina (Al₂O₃) layer on the hydrophilic layer by reacting gaseous tri-methyl aluminum (TMAl) with the hydrophilic layer; and
forming an insulating layer which fills in the trench by growing the alumina layer by reacting tris-(tert-alkoxy)-silanol with the alumina layer.

5. The method of claim 4, comprising forming the alumina layer and the buried insulating layer by a rapid vapor deposition process at a vapor pressure in the range of 1 Torr to 20 Torr and at a temperature in the range of 150° C. to 300° C.

6. A method of forming an isolation layer in a semiconductor device using rapid vapor deposition, the method comprising:
forming a trench in an isolation region of a semiconductor substrate having an isolation region and an active region;
forming a hydrophobic layer on the trench in the isolation region and on the active region;
forming an oxide layer on the hydrophobic layer overlying the trench and the isolation region by oxidizing a portion of the hydrophobic layer;
etching the oxide layer formed over the active region to expose the hydrophobic layer in the active region, whereby the oxide layer remains in the isolation region; and
forming a buried insulating layer over the oxide layer filling in the trench in the isolation region but not covering the exposed hydrophobic layer.

7. The method of claim 6, wherein the hydrophobic layer comprises a polysilicon layer.

8. The method of claim 6, comprising forming the hydrophobic layer by a low pressure chemical vapor deposition (LPCVD) process at a temperature in the range of 500° C. to 530° C.

9. The method of claim 6, comprising forming the oxide layer by an etch-back process.

10. The method of claim 6, comprising forming the oxide layer by anisotropic etching.

11. The method of claim 6, comprising forming the buried insulating layer by:
forming an alumina (Al₂O₃) layer on the oxide layer by supplying gaseous tri-methyl aluminum (TMAl) to the oxide layer for reaction with the oxide layer; and
forming an insulating layer which fills in the trench by supplying tris-(tert-alkoxy)-silanol to the alumina layer to react with the alumina layer to grow the alumina layer.

12. The method of claim 11, comprising forming the alumina layer and the buried insulating layer by a rapid vapor deposition process at a vapor pressure in the range of 1 Torr to 20 Torr and at a temperature in the range of 150° C. to 300° C.
